(19) United States
(12) Patent Application Publication
(10) Pub. No.: US 2017/0200835 A1
(43) Pub. Date: Jul. 13, 2017

(54) METHOD FOR SELECTIVELY COLORING METAL CONTACTS IN OPTOELECTRONIC DEVICE

(71) Applicant: ALTA DEVICES, Inc., Sunnyvale, CA (US)

(72) Inventors: Liguang LAN, Sunnyvale, CA (US); Linlin YANG, Sunnyvale, CA (US); Jian DING, San Jose, CA (US); Brendan KAYES, Los Gatos, CA (US)

(21) Appl. No.: 14/994,961

(22) Filed: Jan. 13, 2016

(51) Int. Cl. H01L 31/02; H01L 31/18; H01L 31/042

(52) U.S. Cl. CPC H01L 31/0201; H01L 31/042; H01L 31/18

(57) ABSTRACT

A method of fabricating an optoelectronic device includes the steps of providing a semiconductor unit and forming a plurality of metal contacts on a surface of the semiconductor unit for electrical conduction. The method further includes the step of forming a plurality of color coating regions on top of the plurality of metal contacts, the plurality of color coating regions imparting a color different than a color of the plurality of metal contacts.

### TECHNICAL FIELD

The present invention relates generally to optoelectronic devices and more particularly to optoelectronic devices with color coating regions on top of the metal contacts thereof.

### BACKGROUND

Solar cells have become a widely used technology to convert light energy to electrical energy. Multiple solar cells assembled together form solar panels and solar matrixes for installation into various environments such as building structures, vehicles and the like. Single solar cell can also be embedded in components of the wearable technology of various sizes. With the wider deployment of solar cells, consideration of being aesthetically compatible with the surroundings becomes increasingly common.

However, it is not common practice to provide solar cells or solar panels with colors or designs other than that is natural of the electrodes and the photovoltaic (“PV”) modules. On the one hand, the electrodes usually feature a comb pattern in its metal color, and PV modules usually feature a brown, black, or blue surface protected by a thin transparent cover. However, these colors and patterns oftentimes do not work well with the surroundings of the solar panels, let alone aesthetically blending with or enhancing the appearance of the surroundings. On the other hand, PV materials require incident light to produce energy via photoelectric effect. Any colored or hinted overlay on the surface of PV materials for the purposes of obtaining more desirable aesthetic colors or patterns nevertheless causes the blocking of the incident light, affecting the power production capability of the PV modules.

Therefore, there exists a need to customize the appearance of the surfaces of solar cells and solar panels such that aesthetical compatibility with various surroundings can be provided and sufficient efficiency of energy production can be maintained at the same time.

### SUMMARY OF THE INVENTION

In one exemplary embodiment in accordance with the present disclosure, a method of fabricating an optoelectronic device includes the steps of fabricating a semiconductor unit and forming a plurality of metal contacts on a surface of the semiconductor unit for electrical conduction. The method further includes the step of forming a plurality of color coating regions on top of the plurality of metal contacts, the plurality of color coating regions imparting a color different than the color of the plurality of metal contacts.

In another exemplary embodiment in accordance with the present disclosure, an optoelectronic device includes a semiconductor unit and a plurality of metal contacts disposed on a surface of the semiconductor unit for electrical conduction. The optoelectronic device further includes a plurality of color coating regions disposed on top of the plurality of metal contacts, the plurality of color coating regions imparting a color different than a color of the plurality of the metal contacts.

In yet another exemplary embodiment in accordance with the present disclosure, a method for forming a plurality of color coating regions for an optoelectronic device is provided. The optoelectronic device includes a semiconductor unit and a plurality of metal contacts disposed on a surface of the semiconductor unit, areas of the surface not disposed with the plurality of metal contacts having a first resist disposed thereon. The method includes the step of positioning a mask on the surface of the semiconductor unit, where areas of the metal contacts covered by the mask correspond to a pattern of the plurality of color coating regions. The method also includes the step of disposing a second resist on the surface, where areas of the plurality of metal contacts covered by the mask have no second resist disposed thereon. The method further includes the steps of removing the mask, disposing a coloring material on the surface such that the areas of the plurality of metal contacts without the second resist have the coloring material disposed thereon, and removing the first resist and the second resist.

In still yet another exemplary embodiment in accordance with the present disclosure, a method for forming a plurality of color coating regions for an optoelectronic device is provided. The optoelectronic device includes a semiconductor unit and a plurality of metal contacts disposed on a surface of the semiconductor unit, areas of the surface not disposed with the plurality of metal contacts having a first resist disposed thereon. The method includes the step of positioning a mask on the surface of the semiconductor unit. The method also includes the step of disposing a coloring material on the surface such that the areas of the plurality of metal contacts not covered by the mask have the coloring material disposed thereon. The method further includes the step of removing the mask and the first resist.

### BRIEF DESCRIPTION OF THE DRAWINGS

Embodiments of the present invention will be better understood from a reading of the following detailed description, taken in conjunction with the accompanying drawing figures in which like reference characters designate like elements and in which:

FIG. 1 is a perspective view of an exemplary optoelectronic device showing a surface and a structure of layers in accordance with an embodiment of the present disclosure;

FIG. 2 is a plan view of the optoelectronic device of FIG. 1 with a mask defining a bus bar and a plurality of fingers on the surface thereof, in accordance with an embodiment of the present disclosure;

FIG. 3A is a plan view of the optoelectronic device of FIG. 2 with a resist applied on the surface thereof and the mask of FIG. 2 removed, in accordance with an embodiment of the present disclosure;

FIG. 3B is a cross sectional view of the optoelectronic device of FIG. 3A;

FIG. 4 is a plan view of the optoelectronic device of FIG. 3A with a first metal forming a bus bar and a plurality of fingers on the surface thereof, in accordance with an embodiment of the present disclosure;

FIG. 5 is a plan view of the optoelectronic device of FIG. 4 with a color region defining mask covering the bus bar and portions of the plurality of metal fingers, in accordance with an embodiment of the present disclosure;

FIG. 6A is a plan view of an exemplary optoelectronic device showing color coating regions on top of the bus bar and the selective metal fingers, in accordance with an embodiment of the present disclosure;

FIG. 6B is a cross section view of a portion of the optoelectronic device of FIG. 6A;

FIG. 7A is an illustration of a surface of an exemplary optoelectronic device showing a pattern of color regions on top of the metal fingers, in accordance with an embodiment of the present disclosure;

FIG.7B is another illustration of a surface of an exemplary optoelectronic device showing another pattern of color regions on top of the metal fingers, in accordance with an embodiment of the present disclosure.

FIG. 7C is a cross section view of a portion of the optoelectronic device of FIG. 7B;

FIG. 8A is an illustration of a surface of an optoelectronic devices showing a first exemplary pattern of color coating regions; and

FIG. 8B is an illustration of a surface of an optoelectronic devices showing a second exemplary pattern of color coating regions.

### DETAILED DESCRIPTION

Reference will now be made in detail to the preferred embodiments of the present invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail so as not to unnecessarily obscure aspects of the embodiments of the present invention. Although a method may be depicted as a sequence of numbered steps for clarity, the numbering does not necessarily dictate the order of the steps. It should be understood that some of the steps may be skipped, performed in parallel, or performed without the requirement of maintaining a strict order of sequence. The drawings showing embodiments of the invention are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part. Generally, the invention can be operated in any orientation.

Notation and Nomenclature:

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “processing” or “accessing” or “executing” or “storing” or “rendering” or the like, refer to the action and processes of a computer system, or similar electronic computing device, that manipulates and transforms data represented as physical (electronic) quantities within the computer system's registers and memories and other computer readable media into other data similarly represented as physical quantities within the computer system memories or registers or other such information storage, transmission or display devices. When a component appears in several embodiments, the use of the same reference numeral signifies that the component is the same component as illustrated in the original embodiment.

Method for Selectively Coloring Metal Contacts in Optoelectronic Device

Embodiments of the present invention are described within the context of providing coating regions on top of the metal contacts of an optoelectronic device, the coating regions imparting a color or pattern different than that of the metal contacts. In that manner, there is no need to allocate areas of the PV surface of the optoelectronic device to accommodate the colors and designs. Examples of such optoelectronic devices include but are not limited to photovoltaic devices, solar devices, semiconductor devices, and any electronic devices (e.g., diodes, light emitting diodes (LEDs), etc.). Examples of such metal contacts of an optoelectronic device include any pattern of electrodes of the optoelectronic device, including but not limited to the finger bus bars configuration.

Herein, the terms “solar module,” and “photovoltaic (PV) module” are used interchangeably; the terms “solar cell” and “PV cell” are used interchangeably. Herein, the terms “front” “back” “top” and “under” are used with reference to the intended orientation of a PV cell when it is installed in position for energy conversion. For example, the front side of the PV cell is intended to face sunlight.

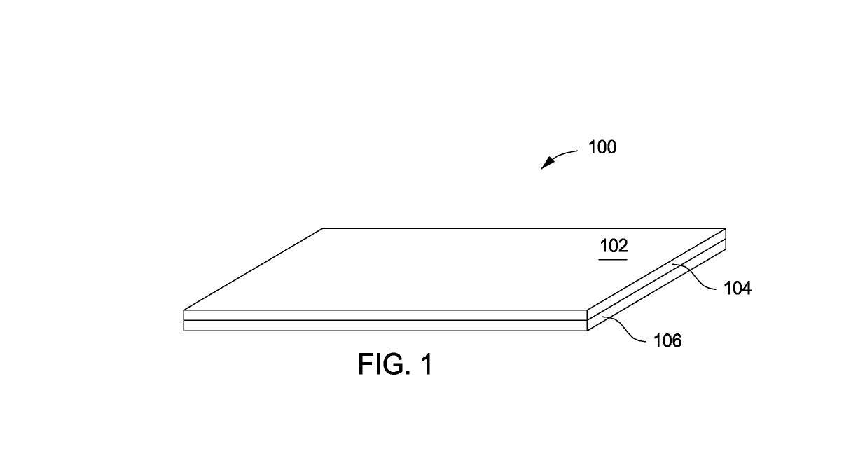

FIGS. 1-6 illustrate an exemplary method of selectively coloring the metal contacts of an optoelectronic device in accordance with embodiments of the present disclosure. The present disclosure is not limited to any specific configuration, structure, dimension, geometry, material composition, fabrication process or application of an optoelectronic device.

FIG. 1 is a perspective view of an exemplary optoelectronic device 100 in accordance with embodiments of the present disclosure. Device 100 may be representative of any semiconductor device, such as, a solar cell, light emitting diode (LED), etc. The optoelectronic device 100 has a PV layer 104 disposed on top of a substrate layer 106. The surface 102 is a surface of the PV layer 104 for disposition of the front electrodes.

The PV layer 104 may include one or more thin film sub-layers based on gallium arsenide (GaAs), aluminum gallium arsenide (AlGaAs), indium gallium phosphide (InGaP), Copper Indium Gallium Selenide (CIGS), Cadmium Telluride (CdTe), amorphous silicon, amorphous microcrystalline tandem, thin-film polycrystalline silicon, or etc. The PV layer may include a number of discrete electrodes (“fingers”) on the surface 102 and an extraction electrode (“bus bar”) connected to all the discrete electrodes for collecting the current generated from the PV layer 104. The PV layer may include a back metal (not shown) disposed on the opposite side of the PV layer where the bus bar and fingers are disposed.

The substrate 106 may be flexible or rigid and made of polymer, silicon, glass, or etc. For example, the substrate may be flexible and may include a pressure sensitive adhesive (PSA) layer, resin layer, epoxy layer, acrylic layer, polyurethane layer, and/or polyester layer, and a polyethylene terephthalate (PET) layer, polyethylene naphthalate (PEN) layer, and/or polyimide layer, or a combination of these. The substrate layer 106 may include layers that provide a buffer for protection, mechanical support, electrical contact, a window, and/or optical reflection, to name a few. The various thickness and relational dimensions of the PV layer 104, substrate layer 106, and other layers of the optoelectronic device as shown in the other figures in this Application, are not drawn to scale and may vary between embodiments of the present disclosure.

The optoelectronic device with selective color coating of the metal contacts may be further treated to include additional layers or modification on both sides of the optoelectronic device. For example, surface 102 of the PV layer 104 can be further treated to include layers of encapsulations, anti-reflective coating or a layer glass. The front electrodes on the surface 102 can also be further wet etched to have a different surface chemistry or surface texture. The substrate layer 106 can also be further treated to include a layer of encapsulations.

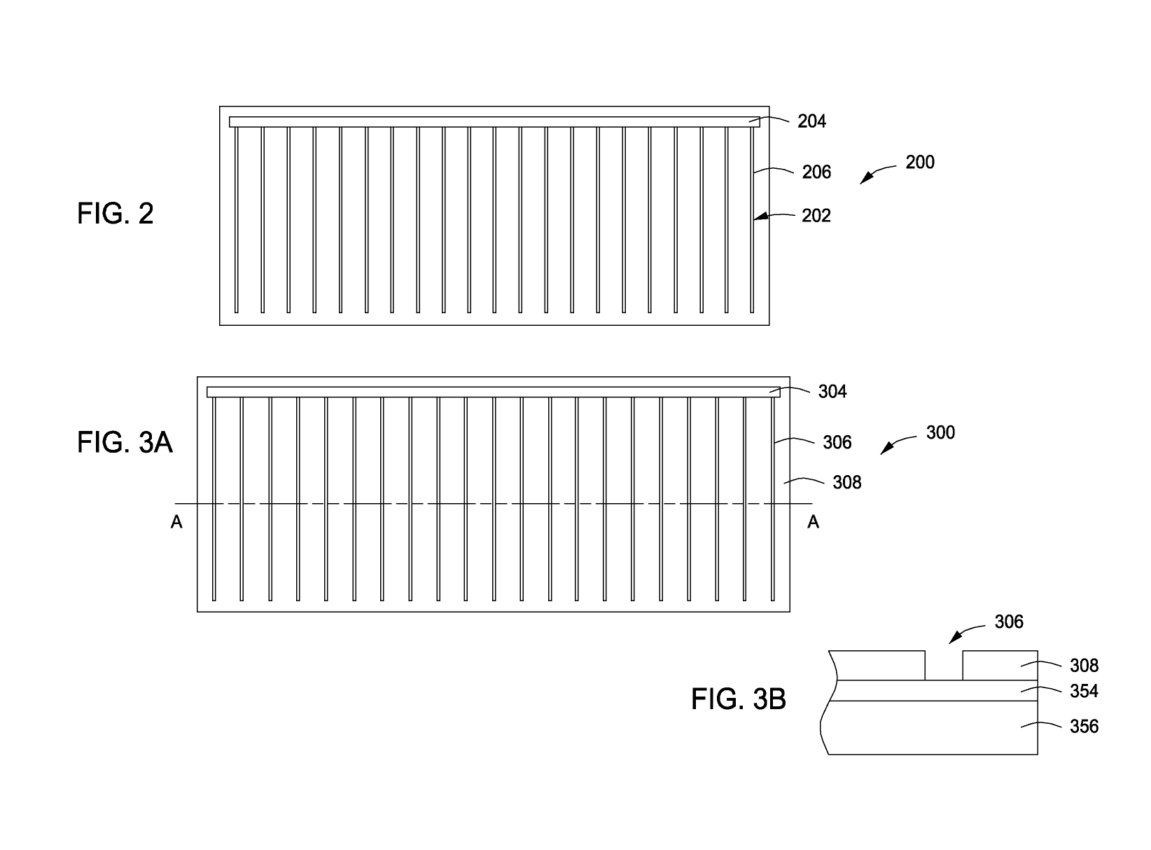

FIG. 2 is a plan view of an optoelectronic device 200, which is modified from the device 100 of FIG. 1 in accordance with embodiments of the present disclosure. The optoelectronic device 200 is shown to include a first mask 202 positioned on the surface of the optoelectronic device. The first mask 202 defines a configuration of the electrodes formed on top of the PV layer 104 for electrical contacts. As shown in FIG. 2, the first mask 202 includes a plurality of metal finger mask portion 206 and a continuous bus bar mask portion 204. In this example, the bus bar mask portion 204 is integrated and in connection to the metal finger mask portions 206; while the plurality of finger mask portions 206 have a uniform length, width, and spacing distance from each other. The bus bar mask portion 204 is configured towards the top section of the surface and the plurality of finger mask portions 206 are perpendicular to the bus bar mask portion 204. Alternatively, the first mask 202 can define a pattern of the front electrodes of any configuration according to designs under the circumstances.

In some embodiments, the first mask can be one integrate piece. In other embodiments, the first mask can have several component sub-masks that define the configuration of the electrodes together. The first mask can be made of any material known in the art that is suitable for preventing a resist (described in below) from being disposed to the areas covered by the first mask. For example, a first mask material can be fabrics, glass, plastic, etc.

FIG. 3A is a plan view of an optoelectronic device 300, which is modified from the optoelectronic device 200 of FIG. 2 in accordance with embodiments of the present disclosure. The modification includes the application of a first resist on the surface of the optoelectronic device 200 and the subsequent removal of the first mask 202 from the optoelectronic device 200. As shown in FIG. 3A, the surface of the optoelectronic device 300 includes areas covered by the first resist, i.e., resist surface areas 308; and areas not covered by the first resist, i.e., expose areas 304 and 306, which are no longer covered by the bus bar mask portion 204 or the finger mask portion 206 either.

FIG. 3B is a cross section view of the optoelectronic device 300 of FIG. 3A, taken along the line A-A. The first resist can be applied by spraying the resist on the surface of the optoelectronic device 200 or any other suitable technique that is well known in the art. As the first mask 202 prevents the first resist from depositing on the area covered by the first mask 202, after the application to the surface, the first resist material forms a layer 308 on top of the PV layer 354. After the first mask 202 is removed, the areas covered by the first mask 202 leaves a plurality of recesses 306 among the layer 308. As shown here, the recesses 306 correspond to the expose areas 306 (expose area 304, not shown in FIG. 3B, are in the form of recess as well), with no depositing of the first resist and separated by the first resist layer 308. At this point, the configuration of the opening of the first mask 202 is transferred to the surface of the optoelectronic device 300. The PV layer 354 is the PV layer 104 of FIG. 1 and the substrate layer 356 is the substrate layer 106 of FIG. 1.

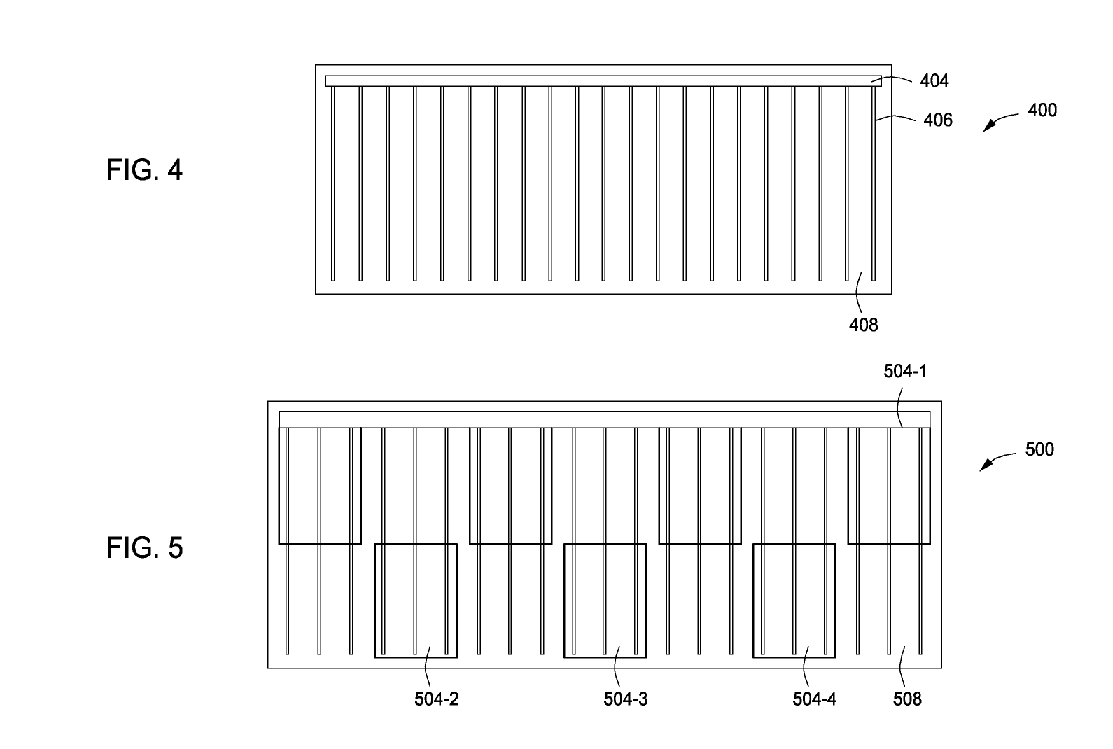

FIG. 4 is a plane view of an optoelectronic device 400, which is modified from the optoelectronic device 300 of FIG. 3 in accordance with embodiments of the present disclosure. The optoelectronic device 400 is shown to have the first metal deposited in the expose areas 304 and 306 of FIG. 3, forming the bus bar 404 and the plurality of metal fingers 406. The first metal can be of any metal that is suitable for forming electrodes on the surface of a PV layer. For example, the first metal material can be Cu or composite metals of Cu. The first metal can be deposited by plating, sputtering, co-vaporizing, Low Pressure Chemical Vapor Deposition (LPCVD), Plasma-Enhanced Chemical Vapor Deposition (PECVD), or any other suitable technique that is well known in the art.

As the first resist prevents the first metal from being disposed directly on the surface of the PV layer, only the expose areas 304 and 306 on top of the PV layer have the first metal disposed thereon and forming a pattern of the electrodes, which will not be removed upon the removal of the first resist. At this point, the surface of the optoelectronic device 400 includes the bus bar 404, the plurality of metal fingers 406, and areas 408-covered by the first resist.

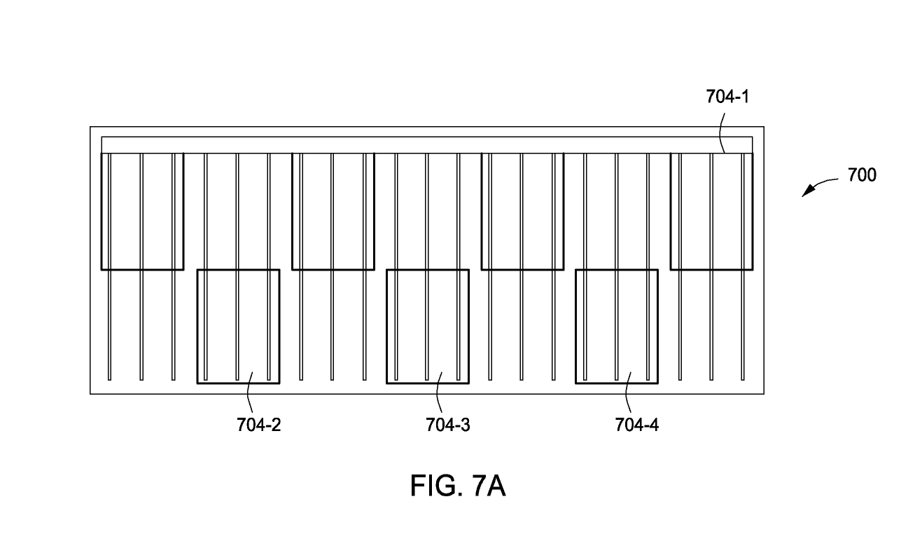

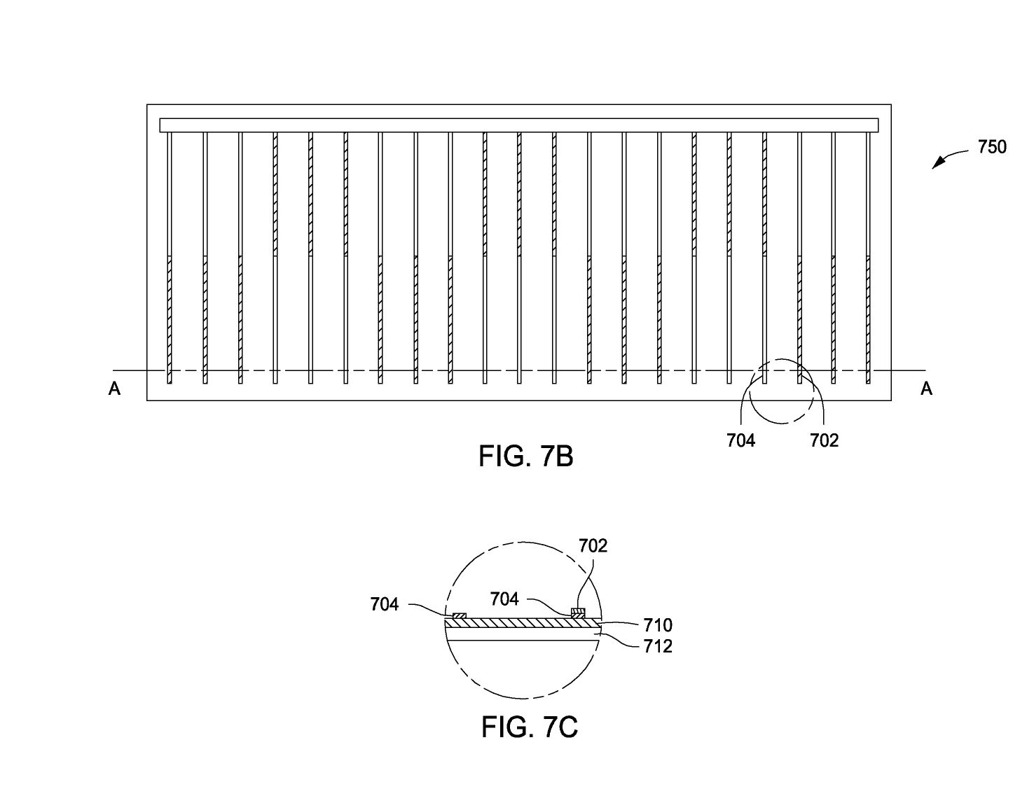

FIG. 5 is a plan view of an optoelectronic device 500, which is modified from the optoelectronic device 400 of FIG. 4 in accordance with embodiments of the present disclosure. The optoelectronic device 500 is shown to have a second mask positioned on top of the surface of the optoelectronic device 400. The areas of the metal contacts covered by the second mask define the configuration of the plurality of colored regions on top of the metals contacts. The second mask can define any pattern according to a design for the surface of the optoelectronic device. For example, the second mask can define a uniform appearance, e.g., darkening all the metal contacts to match the background color imparted by the PV layer and the substrate layer such that the comb pattern of the bus bar and metal fingers is no longer visible. Alternatively, the second mask can also define patterns as illustrated in FIGS. 7A-7B, which are appearances customized for aesthetic compatibility requirements.

Further, the second mask can be one integrate piece or include multiple component sub-masks defining the configuration of the colored regions on top of the metal contacts as a whole. As shown in FIG. 5, the second mask includes a sub-mask 504-1 positioned on the bus bar section of the surface for covering the entire bus bar and portions of three fingers till their half length for the first, third, fifth and seventh set of three fingers. The second mask also includes sub- masks 504-2, 504-3 and 504-4, all of which are positioned for covering the other metal fingers for half length of the second, fourth and sixth set of three fingers respectively. At this point, the surface of the optoelectronic device 500 includes the second mask, the metal contacts uncovered by the second mask, and the areas 508 covered by the first resist.

The second mask can be made of any material known in the art that is suitable for preventing the second resist from being disposed on the covered metal contacts. The second mask and the first mask can be made of the same or different materials.

Given the fact that the metal fingers in general have a width of from about 50 μm to about 100 μm, the degree of precision of designing the first mask is relatively high and the shift tolerance of the first mask is relatively low. However, because the surface areas 508 of the PV layer are still covered by the first resist, which prevents a coloring material from being disposed on the PV layer, the degree of precision of designing the second mask is relatively low, and the shift tolerance of the second mask is relatively high, e.g., less than half of the spacing distance. For example, the sub-mask 504-2 is made much larger here to cover portions of the sets of the three fingers and the spacing areas between them, eliminating the need to design and position the second mask with a width of 50 μm to 100 μm for covering the portions of the three fingers individually.

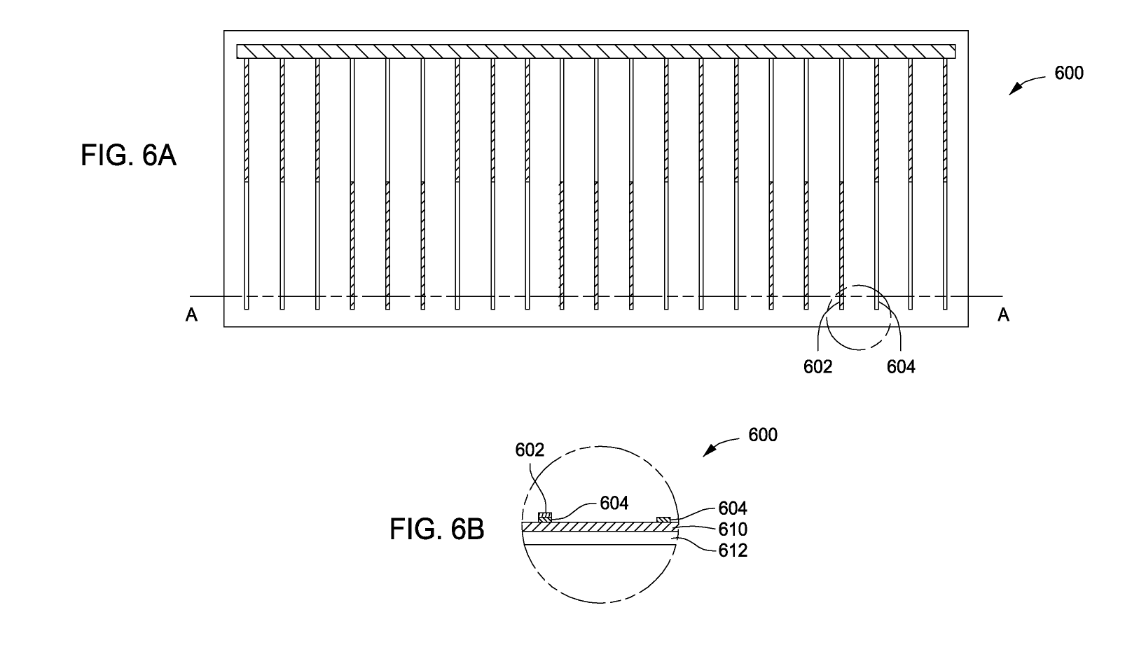

FIG. 6A is a plan view of an optoelectronic device 600, which is modified from the optoelectronic device 500 in accordance with embodiments of the present disclosure. The modification includes four steps: the application of the second resist to the surface of optoelectronic device 500, the removal of the second mask from the surface of the optoelectronic device 500, the disposing of the coloring material, and the removal of the first resist and the second resist from the surface of the optoelectronic device 500. The optoelectronic device 600 is shown to have a plurality of color coating regions 602 on top of the metal fingers, a plurality of portions of the metal fingers 604 without the color coating, and a bus bar with the color coating.

The second resist is applied such that the portions of the metal contacts covered by the second mask do not have the second resist disposed thereon. With the removal of the second mask, the portions of the metal fingers no longer covered by the second mask become expose portions, which have neither the first resist nor the second resist disposed thereon. Subsequently, after the disposition of a coloring material on the surface of the optoelectronic device, only those expose portions of the metal contacts have the coloring material directly disposed thereon, which cannot be removed upon the removal of the second resist or the first resist. The first resist and the second resist can be the same or different resist materials.

After the removal of both the first resist and the second resist, which can be done by the lift-off technique or any other suitable technique known in the art, the bus bar and the plurality of metal fingers remain disposed on top of the PV layer, the regions of color coating also remain disposed on top of the metal contacts, forming selectively coated color regions 602 on top of the metal contacts.

FIG. 6B is a cross section view of the circled portion of the optoelectronic device 600 of FIG. 6A, taken along the line A-A. The circled portion of the optoelectronic device 600 shows two metal fingers 604 disposed on top of the PV layer 610, which is configured on top of the substrate layer 612. The metal finger 604 to the left further includes a color coating region 602 on top thereof, the neighboring metal finger 604 to the right has no color coating. The PV layer 610 is the PV layer 104 of FIG. 1 and the substrate layer 612 is the substrate layer 106 of FIG. 1. The thickness of the metal fingers without a color coating in general ranges from 3 μm about to about 7 μm. The thickness of the color coating can be much less as long as sufficient color can be imparted with the coating.

Alternatively, when the second mask defines a uniform appearance for the metal contacts, e.g., all coated with a dark color to match the background PV color of the optoelectronic device, the second mask and the second resist is no longer necessary as the surfaces of all the metal contacts are already exposed, and the PV portions are still protected by the first resist. For example, a dark colored second metal can be plated on the surface where the bus bar, the plurality of metal fingers and the first resist material are disposed. Upon the removal of the first resist, all the metal contacts have two layers of metal: the first metal layer and the second metal layer disposed on top of the first metal. For another example, a second metal of the same color of the PV layer can be similarly formed on top of the bus bar and the plurality of the metal fingers to cover up the pattern of the bus bar and the metal fingers on the surface of the PV layer. With the bus bar and the metal fingers coated by the second metal of the color of the PV layer, the comb pattern of the bus bar and metal finger configuration, or any configuration of the front electrodes, can be concealed in the background color of the underneath PV layer; thereby the entire incident light surface of the optoelectronic device imparts a uniform color, i.e., the color of the PV layer.

Further alternatively, the second mask can also define a negative image of the color coating pattern for the metal contacts. In this case, the second mask functions as both the color coating pattern defining mask and the second resist, and the application of the second resist is not necessary. After the application of the coloring material and the removal of the first resist and the second mask, the portions of the metal contacts uncovered by the second mask have the coloring material disposed thereon, the portions of the metal contacts covered by the second mask retain the first meal color and have no coloring material disposed thereon.

In addition to utilizing a second mask and a second resist in combination with disposing of coloring materials on top of the metal fingers and bus bar, a second mask and an etch resist in combination with etching of coloring materials previously disposed on the metal contacts can also be utilized to achieve a color or pattern of a design. FIG. 7A is a plan view of an optoelectronic device 700 having a coloring material disposed on top of the first metal, i.e., the bus bar and the plurality of the fingers.

The optoelectronic device 700 is also show to have a second mask positioned on top of the surface in accordance with embodiments of the present disclosure. The areas of the color coated metal contacts covered by the second mask define the configuration of the plurality of the first metal regions to be exposed, i.e., have no coating of the coloring material after the etching. The areas of the color coated metal contacts not covered by the second mask define the configuration of the plurality of the regions of the coloring material that are to remain on top of the first metal after the etching. For example, when the coloring material has the same color of the PV layer, the areas not covered by the second mask will reveal the color of the first metal upon the removal of the coating of the color material by etching. The second mask can define any pattern according to a design for the surface of the optoelectronic device.

Similarly, the second mask can be one integrate piece or include multiple component sub-masks defining the configuration of the regions on top of the metal contacts without the coating of the color material. As shown in FIG. 7A, the second mask includes a sub-mask 704- lpositioned on coated the bar bus section of the surface for covering the entire coated bus bar and portions of coated three fingers till their half length for the first, third, fifth and seventh set of three fingers. The second mask also includes sub-masks 704-2, 704-3 and 704-4, all of which are positioned for covering the other coated metal fingers for half length of the second, fourth and sixth set of three fingers respectively. At this point, the surface of the optoelectronic device 700 includes the second mask, the color material coated metal contacts uncovered by the second mask, and the remaining areas that may or may not be covered by the first resist and the second resist from the process of forming the coating of the coloring material on the front electrodes.

FIG. 7B is a plan view of an optoelectronic device 750, which is modified from the optoelectronic device 700 of FIG. 7A in accordance with embodiments of the present disclosure. The modification includes four steps: the application of the etch resist to the surface of optoelectronic device 700, the removal of the second mask from the surface of the optoelectronic device 700, the etching of the coloring material, and the removal of the etch resist and the first resist if any from the optoelectronic device 700. The optoelectronic device 750 is shown to have a plurality of remaining color coating regions 702 on top of the metal fingers, a plurality of portions of the metal fingers 704 exposed, i.e., having the color coating removed, and a bus bar having the color coating removed as well.

The etch resist is applied such that the portions of the color coated metal contacts covered by the second mask do not have the etch resist disposed thereon. With the removal of the second mask, the portions of the color coated metal fingers no longer covered by the second mask become expose portions, which have no etch resist disposed thereon. Subsequently, after the etching of the coating of the coloring material on the surface of the optoelectronic device, only those expose portions of the coated metal contacts have the coloring material removed. The portions of the coated metal contacts covered by the etch resist retain the color coating since the etch resist protects the coloring material from being etched away.

After the removal of the etch resist, and the first resist and the second resist if any, the portions of the color coating previously disposed on the bus bar and the plurality of metal fingers that are covered by the etch resist remain disposed on top of the bus bar and the plurality of metal fingers. The portions of the color coating not protected by the etch resist are etched away such that the color of the underneath layer of the front electrodes is revealed.

FIG. 7C is a cross section view of the circled portion of the optoelectronic device 750 of FIG. 7B, taken along the line A-A. The circled portion of the optoelectronic device 750 shows two metal fingers 704 disposed on top of the PV layer 710, which is configured on top of the substrate layer 712. The metal finger 704 to the right further includes a color coating region 702 on top thereof, the neighboring metal finger 704 to the left has no color coating due to the etching process. The PV layer 710 is the PV layer 104 of FIG. 1 and the substrate layer 712 is the substrate layer 106 of FIG. 1.

The coloring material can be any material known in the art that can produce visible colors on top of the metal contacts of the optoelectronic device. For example, the coloring material can be colored conductive materials such as Ag, Au, Cu, ZnO, Sn, etc., or compound metals. The coloring material can also be colored non-conductive material such as ink of a single color or multiple colors, paint of a single color or multiple colors, or plastic of a single color or multiple colors, etc. When the coloring material is a second metal, the same techniques known in the art to dispose the first metal contacts onto the surface of the optoelectronic device can be used. For example, the second metal can be plated to the surface of the first metal contacts. The non-conductive materials can be disposed on the surface by printing, reactive sputtering, vaporization or any other suitable technique that is well known in the art.

Alternatively, the coloring material can also be any material that changes the color of the metal contacts by a treatment or reaction process. For example, metal contacts made of Cu can be treated by oxidation or sulfur treatment to generate a layer of CuO or CuS respectively on top of the Cu contacts. Because CuO and CuS impart a color different than that of Cu, the oxide layer and sulfide layer form a color coating on top of the metal contacts.

Multiple first masks, multiple second masks, multiple colors, multiple layers of color coating, combination of the use of different types of coloring materials, combination of the use of depositing and etching can be implemented such that an appearance according to a design or a change to a design can be achieved on the surface of the optoelectronic device. In some embodiments, the bus bar of the optoelectronic device needs to retain its electrical conductivity such that electronic connections to other optoelectronic devices or electrical components can be retained. In this case, the bus bar can be colored with conductive materials such that sufficient electrical conductivity can be maintained, regardless how the coloring material is disposed on top of the metal fingers.

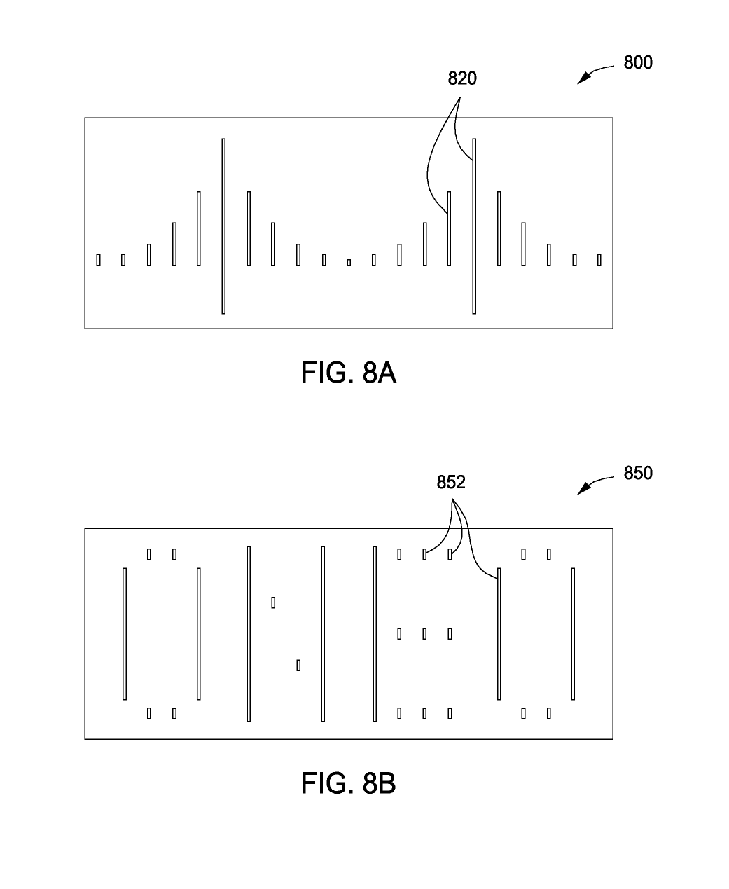

FIGS. 8A-8B are illustrations of a surface of an optoelectronic devices showing exemplary pattern of color coating regions on top of the metal contacts, in accordance with embodiments of the present disclosure. FIG. 8A shows an optoelectronic device 800 having a generally dark background and a plurality of visible finger regions 820 with a uniform design. Here, portions of the metal fingers and the bus bar are selectively colored with the color of the background of the optoelectronic device 800.

As shown in FIG. 8B, the optoelectronic device 850 shows a design 852 of a string of letters “ONEO” on top of the metal fingers. Again, the portions the metal fingers and the entire bus bar, which are not part of the letters “ONEO”, are selectively colored with the color of the background of the optoelectronic device 850.

Further, an optoelectronic device can be assembled together with other optoelectronic devices to form a solar panel and solar matrix. Depending on the configuration of the topology of the solar cell assembly, metal contacts of individual device can be color coated differently to provide for an overall design of appearance for the entire solar panel or solar matrix. Furthermore, metal contacts such as bus bars and fingers that are not visible in the assembly (e.g., overlayed by portions of other optoelectronic device or other assembly components) accordingly do not need to have color coating regions formed on top thereof. For example, if the bus bar is hidden and invisible in a solar panel, there is no need to color coat the bus bar with a second metal.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

1. A method of fabricating an optoelectronic device, the method comprising the steps of:
fabricating a semiconductor unit;
forming a plurality of metal contacts on a surface of the semiconductor unit for electrical conduction; and
foiniing a plurality of color coating regions on top of the plurality of metal contacts, wherein the plurality of color coating regions impart a color different than a color of the plurality of metal contacts.

2. The method of claim 1, wherein the plurality of color coating regions are formed by disposing a coloring material on top of the plurality of metal contacts.

3. The method of claim 1, wherein the step of forming a plurality of color coating regions comprises the steps of:
positioning a mask on the surface with the plurality of metal contacts, wherein areas of the plurality of metal contacts covered by the mask corresponds to a pattern of the plurality of color coating regions, areas of the surface without the plurality of metal contacts are covered by a first resist;
disposing a second resist on the surface, wherein areas of the plurality of metal contacts covered by the mask have no second resist disposed thereon;
removing the mask;
disposing a coloring material on the surface such that the areas of the plurality of metal contacts without the second resist have the coloring material disposed thereon; and
removing the first resist and the second resist.

4. The method of claim 1, wherein the step of foil ling a plurality of color coating regions comprises the steps of:
positioning a mask on the surface with the plurality of metal contacts, wherein areas of the surface without the plurality of metal contacts are covered by a first resist;
disposing a coloring material on the surface such that the areas of the plurality of metal contacts not covered by the mask have the coloring material disposed thereon; and
removing the mask and the first resist.

5. The method of claim 1, wherein the plurality of color coating regions are formed by a coloring material reaction that changes a color of a portion of the plurality of metal contacts.

6. The method of claim 1, wherein a color region of the plurality of color regions comprises a conductive material.

7. The method of claim 1, wherein a color region of the plurality of color regions comprises a non-conductive material.

8. The method of claim 6, wherein the plurality of color regions are formed by plating a second metal on top of the plurality of metal contacts.

9. The method of claim 1, wherein a color region of the plurality of color regions is removed to expose the color of the metal contact.

10. The method of claim 9, wherein the color region is removed by etching.

11. The method of claim 1, wherein the optoelectronic device is incorporated into an optoelectronic panel such that the plurality of color coating regions impart a portion of a pattern of the optoelectronic panel.

12. An optoelectronic device comprising:
a semiconductor unit;
a plurality of metal contacts disposed on a surface of the semiconductor unit for electrical conduction; and
a plurality of color coating regions on top of the plurality of metal contacts, wherein the plurality of color coating regions impart a color different than a color of the plurality of the metal contacts, and wherein each color coating region corresponds to multiple metal contacts from the plurality of metal contacts.

13. The optoelectronic device of claim 12, wherein the plurality of color coating regions are formed by disposing a coloring material on top of the plurality of metal contacts.

14. The optoelectronic device of claim 12, wherein the plurality of color coating regions are formed by a coloring material reaction that changes a color of a portion of the plurality of metal contacts.

15. The optoelectronic device of claim 12, wherein a color coating region of the plurality of color regions comprises a conductive material.

16. The optoelectronic device of claim 12, wherein a color coating region of the plurality of color regions comprises a non-conductive material.

17. The optoelectronic device of claim 12, wherein a color coating region of the plurality of color coating regions is removed to expose the color of the metal contact.

18. The optoelectronic device of claim 12, wherein the optoelectronic device is incorporated into an optoelectronic panel such that the plurality of color coating regions impart a portion of a pattern of the optoelectronic panel.

19. A method for providing a color or pattern for an optoelectronic device, the optoelectronic device comprising a plurality of metal contacts disposed on a surface of a semiconductor unit, areas of the surface not disposed with the plurality of metal contacts having a first resist disposed thereon, the method comprising the step of forming a plurality of color coating regions on top of the plurality of metal contacts, wherein the plurality of color coating regions impart a color different than a color of the plurality of metal contacts.

20. The method of claim 19, wherein the plurality of color coating regions are formed by disposing a coloring material on top of the plurality of metal contacts.

21. The method of claim 19, wherein step of forming a plurality of color coating regions comprises the steps of:
positioning a mask on the surface, wherein areas of the metal contacts covered by the mask corresponds to a pattern of the plurality of color coating regions;
disposing a second resist on the surface, wherein areas of the plurality of metal contacts covered by the mask have no second resist disposed thereon;
removing the mask;
disposing a coloring material on the surface such that the areas of the plurality of metal contacts without the second resist have the coloring material disposed thereon; and
removing the first resist and the second resist.

22. The method of claim 19, wherein the step of forming a plurality of color coating regions comprises the steps of:
positioning a mask on the surface with the plurality of metal contacts;
disposing a coloring material on the surface such that the areas of the plurality of metal contacts not covered by the mask have the coloring material disposed thereon; and
removing the mask and the first resist from the surface.

23. The method of claim 19, wherein the plurality of color coating regions are formed by a treatment of a coloring material that changes a color of a portion of the plurality of metal contacts.

24. The method of claim 19, wherein a color region of the plurality of color regions comprises a conductive material.

25. The method of claim 19, wherein a color region of the plurality of color regions comprises a non-conductive material.

26. The method of claim 19, wherein a color region of the plurality of color regions is removed to expose the color of the metal contact.

27. The method of claim 19, wherein the optoelectronic device with the plurality of color coating regions is incorporated into an optoelectronic panel such that the plurality of color coating regions impart a portion of a pattern of the optoelectronic panel.

28. The optoelectronic device of claim 12, wherein the plurality of color coating regions are configured in a pattern on the semiconductor unit.

29. The optoelectronic device of claim 28, wherein the pattern is a staggered pattern where the plurality of color coating regions alternate their position on top of the plurality of metal contacts.

30. The optoelectronic device of claim 28, further comprising a bus bar on the surface of the semiconductor unit and connected to an end of each of the plurality of metal contacts, wherein the pattern is such that a first subset of the plurality of color coatings are on top of the plurality of metal contacts near the bus bar and a second subset of the plurality of color coatings are on top of the plurality of metal contacts away from the bus bar.
